(19) United States
(12) Patent Application Publication
(10) Pub. No.: US 2019/0252467 A1
(43) Pub. Date: Aug. 15, 2019

(54) DISPLAY PANEL, METHOD FOR MANUFACTURING THE SAME AND DISPLAY DEVICE

(71) Applicants: Liang CHEN, Beijing (CN); Lei WANG, Beijing (CN); Xiaochuan CHEN, Beijing (CN); Minghua XUAN, Beijing (CN); Shengji YANG, Beijing (CN); Dongni LIU, Beijing (CN); Han YUE, Beijing (CN); Ming YANG, Beijing (CN); Li XIAO, Beijing (CN); Pengcheng LU, Beijing (CN)

(72) Inventors: Liang CHEN, Beijing (CN); Lei WANG, Beijing (CN); Xiaochuan CHEN, Beijing (CN); Minghua XUAN, Beijing (CN); Shengji YANG, Beijing (CN); Dongni LIU, Beijing (CN); Han YUE, Beijing (CN); Ming YANG, Beijing (CN); Li XIAO, Beijing (CN); Pengcheng LU, Beijing (CN)

(21) Appl. No.: 16/243,641

(22) Filed: Jan. 9, 2019

(30) Foreign Application Priority Data
Jan. 19, 2018 (CN) 201810055459.X

(51) Int. Cl. H01L 27/32; H01L 51/52; G06F 3/041

(52) U.S. Cl. CPC H01L 27/323; H01L 27/3276; G06F 2203/04103; G06F 3/0412; H01L 2227/323; H01L 51/5221

(57) ABSTRACT

A method for manufacturing a display panel including a substrate and a light emitting functional layer on the substrate comprises the following steps: forming a conductive wire on the substrate; forming a semiconductor layer on the conductive wire; forming a conductive channel in the semiconductor layer, the conductive channel connects to the conductive wire; and forming a first electrode layer on the semiconductor layer and the light emitting functional layer, wherein the first electrode layer connects with the conductive channel. The present disclosure can reduce a length of a wiring trace between the electrode layer and the conductive wire, and avoid a touch blind region on the display panel caused by the excessively large wiring trace region.

### CROSS-REFERENCE TO RELATED APPLICATION

This application claims a priority to Chinese Patent Application No. 201810055459.X, entitled with “Display Panel, Method for manufacturing the same, and Display Device”, submitted on Jan. 19, 2018, the disclosure of which is incorporated herein in its entirety by reference.

### TECHNICAL FIELD

The present disclosure relates to a field of display technology, particularly to a display panel, a method for manufacturing the same and a display device.

### BACKGROUND

With a rapid development of a display technology, an Organic Light Emitting Diode (OLED) is the best choice for next-generation display due to its fast response speed, higher contrast, wide viewing angle, ultra-thin, low power consumption and flexibility etc. The touch modes of an OLED product (such as a display panel) include on-cell embedded touch technology and In-cell embedded touch technology.

However, the OLED product and/or its touch technology still need to be improved.

### SUMMARY

The present disclosure firstly provides a method for manufacturing a display panel, comprising:

forming a conductive wire on the substrate;

forming a semiconductor layer on the conductive wire;

forming a conductive channel in the semiconductor layer, the conductive channel connects to the conductive wire; and

forming a first electrode layer on the semiconductor layer and the light emitting functional layer, wherein the first electrode layer connects with the conductive channel.

Optionally, forming a conductive channel in the semiconductor layer comprises injecting a material containing a conductive particle into the semiconductor layer by ion implantation to form the conductive channel.

Optionally, the semiconductor layer comprises an organic semiconductor material.

Optionally, forming a conductive channel in the semiconductor layer comprises:

covering a mask having a transmissive region over the semiconductor layer; and

performing ion implantation on a region of the semiconductor layer corresponding to the transmissive region to form the conductive channel in the region of the semiconductor layer corresponding to the transmissive region.

Optionally, the conductive channel extends from a side of the semiconductor layer away from the substrate to the conductive wire.

Optionally, the mask comprises a photoresist or a metal.

Optionally, the conductive particle is at least one selected from the group consisting of a B³⁺ ion, a P³⁻ ion, an I⁻ ion, an organic conductive ion, an organic conductive atom and an organic conductive molecule.

Optionally, the method for manufacturing a display panel further comprises the step of sequentially forming an encapsulating film, an optical adhesive, and a cover plate on the first electrode layer.

Optionally, patterns of the conductive wire layer and the semiconductor layer are simultaneously formed by the same mask.

Optionally, the method for manufacturing a display panel further comprises the step of forming an insulating layer on the substrate to isolate the conductive wire layer and the semiconductor layer from the light emitting functional layer.

Optionally, the first electrode is multiplexed into a cathode of the light emitting function layer and a touch electrode, and segmentation of the first electrode layer is performed using a barrier technique to divide the first electrode layer into a plurality of mutually insulated sub-electrodes.

Optionally, a projection of the barrier on the substrate does not overlap with a projection of the conductive channel on the substrate. A material for forming the barrier is selected from at least one of an insulating inorganic material, an organic polymer material, and a photoresist.

Optionally, the barrier is an inverted trapezoidal spacer column.

The present disclosure also relates to a display panel comprising:

a substrate,

a conductive wire and a light emitting functional layer on the substrate,

a semiconductor layer on the conductive wire,

a first electrode layer on the light emitting functional layer and the semiconductor layer,

wherein the semiconductor layer is further provided with a conductive channel, and the first electrode layer is conductive to the conductive wire through the conductive channel.

Optionally, the conductive channel comprises a conductive particle, and the conductive particle is selected from the group consisting of a B³⁺ ion, a P³⁻ ion, an I⁻ ion, an organic conductive ion, an organic conductive atom and an organic conductive molecule.

Optionally, the display panel is manufactured by including a method comprising the steps of:

forming a conductive wire on the substrate;

forming a semiconductor layer on the conductive wire;

forming a conductive channel in the semiconductor layer, the conductive channel connects to the conductive wire; and

forming a first electrode layer on the semiconductor layer and the light emitting functional layer, the first electrode layer connects to the conductive channel.

Optionally, the conductive channel is formed by injecting a material containing a conductive particle into the semiconductor layer by ion implantation.

Optionally, a longitudinal axis of the conductive channel is perpendicular to both a surface of the semiconductor layer away from the substrate and a surface of the substrate.

The present disclosure also provides a display device including the display panel as described above.

Accordingly, the present disclosure also provides a display panel, which is manufactured by the method for manufacturing the display panel according to any of the above aspects.

These and other aspects of the present disclosure will be more apparent and readily understood from the following description of the embodiments.

### BRIEF DESCRIPTION OF THE FIGURES

FIG. 1 is a schematic flow chart of a method for manufacturing a display panel according to some embodiments of the present disclosure;

FIG. 2 is a schematic flow chart of forming a conductive channel according to some embodiments of the present disclosure;

FIG. 3 is a schematic diagram of doping conductive particles by ion implantation according to some embodiments of the present disclosure;

FIG. 4 is a schematic structural diagram of a display panel according to some embodiments of the present disclosure;

FIG. 5 is a schematic diagram showing cathode segmentation using an inverted trapezoidal spacer column as a barrier according to some embodiments of the present disclosure.

### REFERENCE NUMERALS

100—substrate, 200—light emitting functional layer, 300—first electrode layer, 210—conductive wire, 220—conductive channel, 230—second electrode layer, 260—spacer column. 301—mask, 250—insulating layer, 251—semiconductor layer

### DETAILED DESCRIPTION

The present disclosure is further described with reference to the drawings and exemplary embodiments, wherein the same reference numerals in the drawings are used to refer to the same elements. Further, if a detailed description of a known technique is not necessary to show the features of the present disclosure, it will be omitted.

The touch modes of an OLED product (such as a display panel) include on-cell embedded touch technology and In-cell embedded touch technology.

In an OLED panel adopting an on-cell embedded touch technology, the touch sensing layer is prepared on a thin film encapsulating film (TFE), thereby reducing the touch sensing panel, making the screen thinner, making the touch more sensitive, and making the color display brighter, but such solution cannot realize integration of the touch and the display driver chip.

In-cell embedded touch technology integrates a touch technology into a LCD panel to achieve fusion of a touch layer and a liquid crystal layer. At present, the IN-CELL technology in the industry is mainly divided into two types, namely, Hybrid IN CELL (HIC) and FULL IN CELL (FIC). In the display panel using OLED FIC technology, the FIC adopts a single-layer touch wiring trace design and a self-capacitance principle to realize multi-touch. In order to solve the signal interference caused due to the integration of the display function and the touch function, the FIC adopts a method of “time-sharing scanning”, which divides unit time into two parts, namely, one for touch scanning and the other for display scanning, which does not interfere with each other, and fundamentally eliminates a hidden danger of signal interference. The OLED In cell touch solution uses a wiring trace in the same layer. When the size of the display panel is increased, such solution may cause the touch blind region formed by the wiring trace region to be too large, which affects the touch effect.

To this end, the aim of the present disclosure is to provide a display panel, a method for manufacturing the same, and a display device to achieve effective connection between a conductive wire and an electrode layer, and reduce a length of a wiring trace between the electrode layer and the conductive wire in a different layer. The display panel, the method for manufacturing the same, and the display device of the present disclosure can also avoid adversely affecting the light emitting function layer.

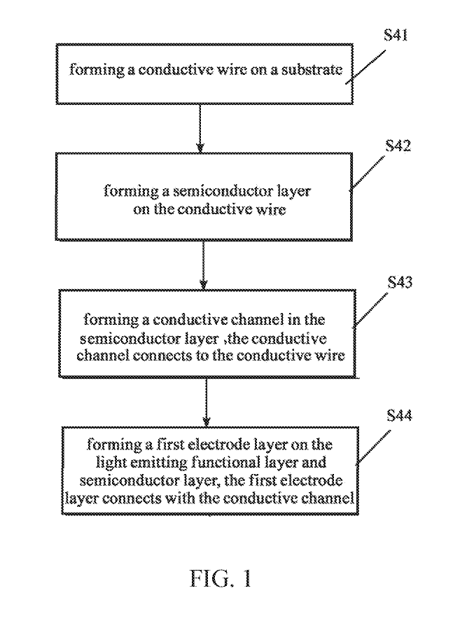

Specifically, some embodiments of the present disclosure provide a method for manufacturing a display panel comprising a substrate and a light emitting functional layer on the substrate, and the schematic flowchart of manufacturing the display panel is as shown in FIG. 1 and includes the following steps:

S41: forming a conductive wire on the substrate;

S42: forming a semiconductor layer on the conductive wire.

Specifically, the conductive wire may be formed on the substrate by evaporation, sputtering, inkjet printing, or the like. The material for forming the conductive wire is preferably a metal, that is, a metal conductive wire; the semiconductor layer is deposited on the conductive wire by sputtering, evaporation, or the like. Preferably, the semiconductor layer covers the conductive wire.

The substrate may be a glass substrate or a flexible substrate, and the substrate may be a substrate on which an insulating protective layer of a pixel electrode is formed.

The semiconductor layer provided by some embodiments of the present disclosure is preferably an organic semiconductor material. The light emitting function layer includes a hole injection layer, a hole transport layer, a light emitting layer, an electron transport layer, and an electron injection layer on a side close to a first electrode layer. Since the carriers in the organic semiconductor are usually localized in the molecule, and the carriers in the inorganic semiconductor are delocalized, a mobility of the carriers in the organic semiconductor is generally lower than that of the inorganic semiconductor. At room temperature, the mobility of the carriers in the organic semiconductor is 10² cm²/(V·s) to 10⁴ cm²/(V·s), while the upper limit of the mobility of the carriers in highly ordered organic semiconductors is about 40 cm²/(V·s). The typical mobility of the carriers in other disordered organic small molecule systems is 10⁻⁴ cm²/(V·s). The mobility of the carrier is an important indicator determining the conductivity of a material. Usually, the conductivity of a material is proportional to the mobility and concentration of the carriers.

As shown in FIG. 1, the method for manufacturing a display panel further includes the following step:

S43: forming a conductive channel in the semiconductor layer, the conductive channel connects to the conductive wire. Preferably, the conductive channel extends from a side of the semiconductor layer away from the substrate to the conductive wire.

The semiconductor layer provided by the present disclosure is preferably an organic semiconductor material, and the organic semiconductor material has a large electrical resistance due to low carrier mobility of the organic semiconductor material. If it is required to open a conductive channel in the semiconductor layer, it is necessary to increase the concentration of the carriers so as to increase the conductivity, and one of the methods for obtaining a higher concentration of the carriers is doping. Since the doping mechanism of an organic semiconductor is different from that of an inorganic semiconductor, the doping concentration of the organic semiconductor is higher than that of the inorganic semiconductor, which is one of the reasons for choosing an organic semiconductor material as a material for the light emitting functional layer. The resistivity of the doped region is reduced by doping a suitable concentration of particles, wherein the doping concentration of the inorganic semiconductor is usually 10⁻⁶, the doping concentration of the organic semiconductor is 1%-5%, and the doping concentration of the conductive polymer is often 20%˜40% or so.

In order to avoid an excessively large wiring trace region, it is conceivable to form a conductive channel by using a through-hole connection or a wiring trace in a different layer so as to realize a large-sized AMOLED embedded touch panel. It is also conceivable to inject a material containing a conductive particle into the semiconductor layer by ion implantation to form a conductive channel. The light emitting layer in the light emitting functional layer is usually prepared by evaporation using a fine metal mask (FMM), and the other functional layers are usually prepared by evaporation using an open mask. The material of the functional layer in the display area is a non-pattered surface layout, and the through-hole connection of the cathode needs to penetrate the organic functional layer. However, the organic material is not resistant to water and oxygen, and when the through-hole of the cathode is prepared by a conventional photolithography process, the organic functional layer is easily damaged, which will affect the display effect of the screen, and even cannot display the screen so that the product is scrapped. Therefore, it is preferable to inject a material containing a conductive particle into the semiconductor layer by ion implantation to form the conductive channel.

The conductive particle include not only a common donor impurity and acceptor impurity particle, such as a B³⁺ ion, a P³⁻ ion, an I⁻ ion, etc., but also other effective organic doping ion, organic doping atom, organic doping molecule, and the like. For example, the specific examples of strong oxidative electron acceptor, strong reducing electron donor, proton acid doping, etc include FeCl₃, MoO₃, CsF, LiF, WO₃ and so on. After doping the conductive particle to the semiconductor layer, the concentration of the carriers in the semiconductor layer is increased, and the conductivity of the doped region in the semiconductor layer is improved.

Ion doping including doping of donor impurity or acceptor impurity is achieved by ion implantation process. The doping method also includes a diffusion doping, but the accuracy thereof is not high and the doping time is too long. Most industries such as semiconductors and panels use ion implantation.

The present disclosure preferably injects the conductive particle as described above into the semiconductor layer by ion implantation. Ion implantation is to irradiate a solid material using an ion beam. The ion beam is resisted by the solid material, so that the ion beam enters the solid material at a slower rate and eventually stays in the solid material. Since the ions are selected by a magnetic analyzer, the particles injected into the semiconductor layer are highly pure. The uniformity of particle doping is good by ion implantation, and the uniformity on the same plane can be generally guaranteed to be ±3%. Moreover, the particle doping by means of ion implantation can precisely control the dose of the implanted particles and the implantation depth, and can ensure the conductivity uniformity of the doped region. Since the temperature required for ion implantation is not high, the thermal defects do not occur, and damage of the light emitting functional layer due to high temperature can be avoided. When ion implantation is performed, it is possible to avoid ion implantation into the coverage area by covering a common photoresist or metal to a region that does not need to be implanted, thereby achieving selective region injection and reducing production cost. Even if the semiconductor crystal lattice is damaged during ion implantation, it can be repaired by a subsequent annealing process.

FIG. 2 is a schematic flowchart showing the formation of a conductive channel in a semiconductor layer, including:

S51: covering a mask having a transmissive region over the semiconductor layer

The position of the transmissive region corresponds to a position at which the conductive wire is projected onto an upper surface of the transmissive region, the upper surface of the transmissive region is a side of the transmissive region away from the substrate, and the width of the transmissive region is less than or equal to the width of the conductive wire projected onto the upper surface of the semiconductor layer. A mask pre-set with the transmissive region is covered over the semiconductor layer, and the mask comprises an anti-implanted layer that can prevent ion implantation, including a photoresist (especially a negative adhesive) or a metal material. The use of the photoresist or the metal as a mask for subsequent ion implantation can effectively prevent the conductive particles entering into the semiconductor layer from entering into a layer other than the conductive channel by ion implantation. Thereby, it realizes particle injection only in the transmitting region, but has no influence on the layer in the non transmitting region, that is, the ion implantation in the selective region is realized. Moreover, since the photoresist and metal are the common materials in display panels, the cost is low and a secondary pollution of the other layer such as the light-emitting functional layer is not caused; and

S52: performing ion implantation on a region of the semiconductor layer corresponding to the transmissive region to form the conductive channel in the region of the semiconductor layer corresponding to the transmissive region

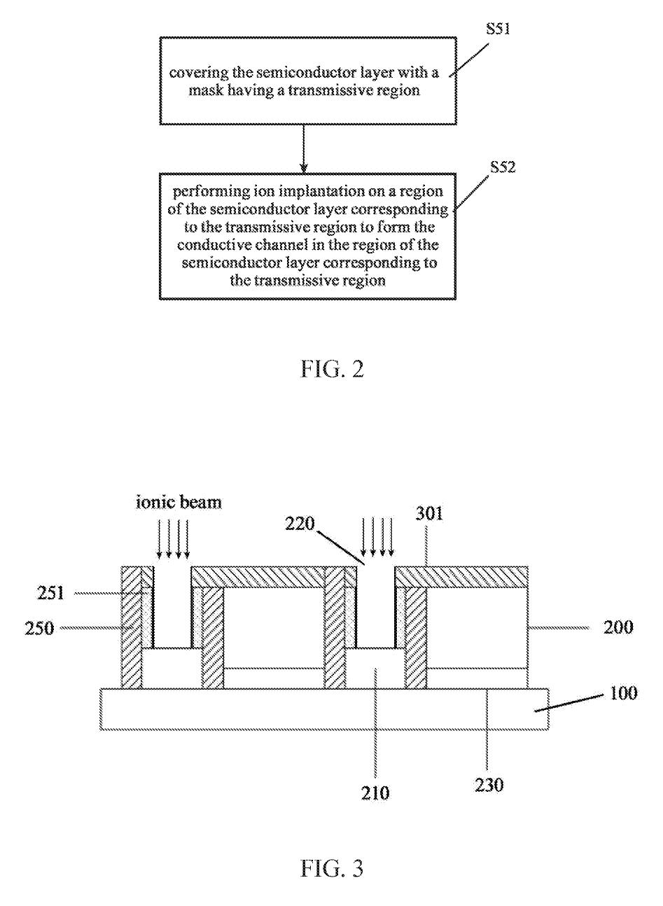

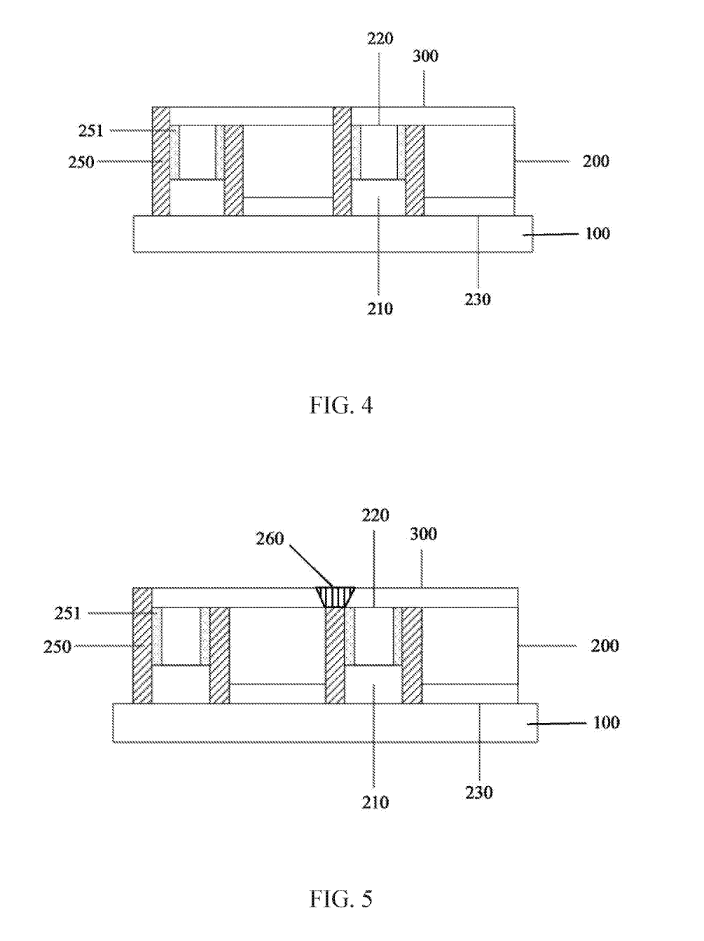

Ion implantation is performed on the region of the semiconductor layer corresponding to the transmissive region, and the conductive particles are injected into the region of the semiconductor layer corresponding to the transmissive region by ion implantation, and the schematic diagram of ion-implanting the doped conductive particles is shown in FIG. 3. Since the conductive particles can increase the concentration of the carriers in the doped region and improve the conductivity of the region, a conductive channel is formed in the region. The conductive channel is formed by ion implantation, which can precisely control the dose of the implanted particles and the implantation depth, and ensure uniform conductivity throughout the conductive channel. In addition, since the temperature required for ion implantation is not high, thermal defects do not occur, and damage of the light emitting functional layer due to high temperature can be avoided.

One end of the conductive channel formed in the semiconductor layer is connected with the conductive wire, and the other end thereof is flush with the upper surface of the semiconductor layer. The end that is flush with the upper surface of the semiconductor layer has no cover layer temporarily. According to the direction of ion implantation, the conductive channel extends from a side of the semiconductor layer away from the substrate to the conductive wire. The axis of the conductive channel may be parallel to the axial direction of the semiconductor layer or may have a certain angle with respective to the axial direction of the semiconductor layer. Preferably, the longitudinal axis of the conductive channel of the present disclosure is parallel to the longitudinal axis of the semiconductor layer. As shown in FIG. 3 and FIG. 4, the longitudinal axis of the conductive channel is perpendicular to the upper surface of the semiconductor layer.

When achieving the conduction of the conductive wire to the first electrode layer, the channel length of the conductive channel of this structure is the shortest, the influence on the other layer (such as the light emitting functional layer) is minimized, the energy consumption and the number of conductive particles by ion implantation are reduced, and the production cost is reduced.

After forming the conductive channel, the method further includes: removing the mask to subsequently form a first electrode layer on the light emitting functional layer and the semiconductor layer. Therefore, as shown in FIG. 1, the method for manufacturing the display substrate further includes:

S44: forming a first electrode layer on the light emitting functional and the semiconductor layer, the first electrode layer connects with the conductive channel

The first electrode layer (such as the cathode layer) is evaporated on the light emitting functional layer and the semiconductor layer, and the first electrode layer segmentation (cathode segmentation) is realized by using an inverted trapezoidal PS. That is, the cathode segmentation is realized by a barrier technique, and the first electrode layer is divided into a plurality of mutually insulated sub-electrodes (such as sub-cathodes), and the plurality of sub-electrodes is multiplexed into a touch electrode. Specifically, before an organic thin film and a metal cathode are evaporated, an insulating barrier is prepared on the substrate to separate the different pixels of the device and thus obtain a pixel array. The plurality of sub-cathodes has dimensions on the order of millimeters. The first electrode layer segmentation is used to achieve touch and display multiplexing, thereby eliminating the need to prepare additional touch sensors, reducing process requirements, reducing costs, and increasing yield.

The position of the barrier does not overlap with the projection of the conductive channel on the substrate. The material of the barrier includes: an insulating inorganic material (such as silicon nitride, silicon carbide, silicon oxide), an organic polymer material (such as PI, polytetrafluoroethylene, etc.), and a photoresist (such as KPR, KOR, KMER, etc.). The barrier in an embodiment of the present disclosure is preferably a spacer column, and the shape of the spacer column may be an inverted trapezoid or a “T” shape. As shown in FIG. 7, the spacer column of the present disclosure is preferably an inverted trapezoidal spacer column 250, wherein the basic method for preparing the inverted trapezoidal spacer column 250 is as follows:

Step 1: spin-coating a first layer of photosensitive organic insulating material on the substrate, wherein the film has a thickness of from 0.5 um to 5 um, the photosensitive organic insulating material is generally a photosensitive PI, and is exposed after pre-baking. The patter after exposure is a mesh structure or a strip structure, and the line width after development is 10 um to 50 um, and then post-baking is performed. Step 2: spin-coating a second layer of photosensitive organic insulating material on the organic insulating material, wherein the film has a thickness of from 0.5 um to 5 um, the photosensitive insulating organic material is generally one of a photoresist in which a line and an interface can form a inverted trapezoidal shape which is larger at the upper portion and smaller at the lower portion after photolithography, generally is a negative adhesive; after a pre-baking, the second layer of the organic insulating material is exposed, the exposure patter is a straight line, and the width after development is 5 um to 45 um.

The cathode is divided into a plurality of sub-cathodes, and the display time of each frame of the touch display panel is divided into a display period and a touch period. During the display period, a common voltage signal is applied to the cathode such that the touch display panel performs display operation, and during the touch time period, the touch scan signal is applied to the cathode, the cathode is multiplexed as a touch electrode to realize the collection of the touch position. Thereby, the purpose of touch control and the purpose of cathode time division multiplexing is achieved, the thickness of the display panel is reduced, and the light transmittance is rendered high.

The display panel in an embodiment of the present disclosure adopts a second electrode layer (such as anode) patterning for segmentation to realize illumination of a single pixel. As shown in FIG. 3 and FIG. 4, the second electrode layer is divided into a plurality of sub-electrode layers, and the material of the electrode layer is a transparent material such as ITO. Tin-doped indium oxide (ITO) containing a compound of indium, tin and oxygen is a representative of a transparent conductive oxide film, and has the advantages of high light transmittance and low resistivity, and can reduce loss of light passing through the layer. A side of the sub-electrode layer away from the substrate corresponds to a light emitting unit provided with a pixel unit.

Since one end of the conductive channel away from the substrate is flush with the upper surface of the light emitting functional layer and the semiconductor layer, and the first electrode layer formed on the light emitting functional layer and the semiconductor layer is also in direct contact with the end of the conductive channel layer away from the substrate to achieve a connection between the first electrode layer and the conductive wire, the conductive wire is not in the same layer as the first electrode layer. Thus, the conductive wire is said to be a heterotopic conductive wire of the first electrode layer. The heterotopic conductive wire (also referred to as an underlying conductive wire) is preferably a conductive wire in the side of the first electrode layer adjacent to the substrate.

By directly forming a conductive channel in the semiconductor layer to connect the first electrode layer and the heterotopic conductive wire, the electrical connection is realized, the length of the wiring trace between the first electrode layer and the heterotopic conductive wire is reduced, and the touch blind region on the display panel caused by the excessively large wiring trace region is avoided.

The method for manufacturing a display panel according to some embodiments of the present disclosure further includes: sequentially forming an encapsulating film, an optical adhesive, and a cover plate on the first electrode layer to complete the manufacture of the entire display panel. The specific process is not limited herein.

Accordingly, the present disclosure also provides a display panel, and the structure of the display panel is as shown in FIG. 4. A display panel comprises: a substrate 100, a conductive wire 210 on the substrate 100, a semiconductor layer 251 on the conductive wire 210, a light emitting functional layer 200 on the substrate and a first electrode layer 300 covering the light emitting functional layer 200 and the semiconductor layer 251; the semiconductor layer 251 is further provided with a conductive channel 220. Preferably, the conductive channel 220 extends from a side of the semiconductor layer 251 away from the substrate 100 to the conductive wire 210. The electrode layer 300 is conductive to the conductive wire 210 through the conductive channel 220.

The display panel may be a touch display panel.

In some embodiments of the present disclosure, the material of the conductive wire 210 is preferably a metal, that is, a metal conductive wire. The substrate 100 may be a glass substrate or a flexible substrate, and the substrate 100 may also be a substrate on which an insulating protective layer of a pixel electrode is formed. The semiconductor layer 251 provided by some embodiments of the present disclosure is preferably an organic semiconductor material. The light emitting functional layer 200 includes a hole injection layer, a hole transport layer, an organic light emitting layer 240, an electron transport layer, and an electron injection layer on a side close to the first electrode layer 300. Since the carriers in the organic semiconductor are usually localized in the molecule, and the carriers in the inorganic semiconductor are delocalized, a mobility of the carriers in the organic semiconductor is generally lower than that of the inorganic semiconductor.

The semiconductor layer 251 provided by the present disclosure is preferably an organic semiconductor material, and the organic semiconductor material has a large electrical resistance due to low carrier mobility of the organic semiconductor material. If it is required to open a conductive channel in the organic functional layer, it is necessary to increase the concentration of the carriers so as to improve the conductivity, and one of the methods for obtaining a higher concentration of the carriers is to conduct conductive particle doping. Since the doping mechanism of an organic semiconductor is different from that of an inorganic semiconductor, the doping concentration of the organic semiconductor is higher than that of the inorganic semiconductor, which is one of the reasons for choosing an organic semiconductor material as a material for the semiconductor layer 251. The resistivity of the doped region is reduced by doping a suitable concentration of particles.

In a preferred embodiment provided by the present disclosure, the conductive particle include a B³⁺ ion, a P³⁻ ion, an I⁻ ion, an organic dopant ion, an organic dopant atom, and/or an organic dopant molecule. The conductive particle include not only a common donor impurity and acceptor impurity particle, such as a B³⁺ ion, a P³⁻ ion, an I⁻ ion, etc., but also other effective organic doping ion, organic doping atom, organic doping molecule, and the like. For example, the specific examples of strong oxidative electron acceptor, strong reducing electron donor, proton acid doping, etc include FeCl₃, MoO₃, CsF, LiF, WO₃ and so on. After doping the conductive particle to the semiconductor layer 251, the concentration of the carriers in the semiconductor layer 251 is increased, and the conductivity of the doped region in the semiconductor layer 251 is improved.

One end of the conductive channel 220 formed in the semiconductor layer 251 is connected with the conductive wire 210, and the other end thereof is flush with the upper surface of the semiconductor layer 251. The end that is flush with the upper surface of the semiconductor layer 251 has no cover layer temporarily. According to the direction of ion implantation, the conductive channel extends from a side of the semiconductor layer 251 away from the substrate to the conductive wire. The axis of the conductive channel 220 may be parallel to the axial direction of the semiconductor layer 251 or may have a certain angle with respective to the axial direction of the semiconductor layer 251. Preferably, the longitudinal axis of the conductive channel 220 of the present disclosure is parallel to the longitudinal axis of the semiconductor layer 251. As shown in FIG. 3 and FIG. 4, the longitudinal axis of the conductive channel 220 is perpendicular to the upper surface of the semiconductor layer 251. When achieving the conduction of the conductive wire 210 to the first electrode layer 300, the channel length of the conductive channel 220 of this structure is the shortest, the influence on the other layer (such as the light emitting functional layer 200) is minimized, the energy consumption and the number of conductive particles by ion implantation are reduced, and the production cost is reduced.

The active matrix organic light emitting diode (AMOLED) in an embodiment of the present disclosure adopts anode patterning for segmentation to realize illumination of a single pixel. As shown in FIG. 3 and FIG. 4, the anode layer 230 is divided into a plurality of sub-anode layers, and the material of the anode layer 230 is a transparent material such as the tin-doped indium oxide (ITO) containing a compound of indium, tin and oxygen. ITO is a representative of a transparent conductive oxide film, and has the advantages of high light transmittance and low resistivity, and can reduce loss of light passing through the layer. A side of the sub-anode layer away from the substrate 100 corresponds to a light emitting unit provided with a pixel unit.

Since one end of the conductive channel 220 away from the substrate 100 is flush with the upper surface of the semiconductor layer 251, and the first electrode layer 300 formed on the semiconductor layer 251 is also in direct contact with the end of the conductive channel layer 220 away from the substrate 100 to achieve a connection between the first electrode layer 300 and the conductive wire 210, the conductive wire 210 is not in the same layer as the first electrode layer 300. Under such case, the conductive wire 210 is said to be a heterotopic conductive wire 210 of the first electrode layer 300. The heterotopic conductive wire 210 (also referred to as an underlying conductive wire 210) is preferably a conductive wire 210 at a side of the first electrode layer 300 adjacent to the substrate 100.

The display panel provided by some embodiments of the present disclosure may also be manufactured by the method for manufacturing the display panel described in the above technical solution.

The display panel provided by some embodiments of the present disclosure conducts the first electrode to the heterotopic conductive wire through the conductive channel in the light emitting function layer, thereby achieving electrical connection between the first electrode layer and the heterotopic conductive wire, reducing the length of the wiring trace between the first electrode layer and the heterotopic conductive wire, avoiding the touch blind region on the display panel caused by the excessively large wiring trace region, and improving the user experience.

In summary, the present disclosure has the following advantages:

In a method for manufacturing the display panel provided by the present disclosure, a conductive channel is formed by injecting conductive particles in the semiconductor layer to reduce the resistivity of the doped region, thereby achieving connection between the first electrode layer and the heterotopic conductive wire, reducing the length of the wiring trace between the first electrode layer and the heterotopic conductive wire, and avoiding the touch blind region on the display panel caused by the excessively large wiring trace region.

In a method for manufacturing the display panel provided by the present disclosure, injecting conductive particles into the semiconductor layer by ion implantation can precisely control the dose of the implanted particles and the implantation depth, and ensure uniform conductivity throughout the conductive channel. In addition, since the temperature required for ion implantation is not high, thermal defects do not occur, and damage of the other layer (such as the light emitting functional layer) due to high temperature can be avoided.

In a method for manufacturing the display panel provided by the present disclosure, the light emitting functional layer is made of an organic semiconductor material. The doping concentration of the organic semiconductor is higher than that of the inorganic semiconductor, which facilitates increasing the doping concentration of the conductive particles, reducing the resistivity of the conductive channel formed by the doped conductive particles, and better connecting the first electrode layer with the conductive wire. Thus, the conductive channel does not cause a large power loss when the display panel is energized.

The display panel provided by the present disclosure connects the first electrode layer to the conductive wire through the conductive channel in the semiconductor layer, thereby reducing the length of the wiring trace between the first electrode layer and the conductive wire, avoiding the touch blind region caused by the excessively large wiring trace region, improving the touch effect of the display panel and improving the user experience.

In addition, the display device provided by the present disclosure is improved on the basis of the above display panel, and therefore, the display device naturally inherits all the advantages of the display panel.

Accordingly, the present disclosure also provides a display device including the display panel of any of the foregoing technical solutions. The display device can be any product or component having a display function such as an electronic paper, an OLED panel, a mobile phone, a tablet computer, a television, a display, a notebook computer, a digital photo frame, a navigator, and the like.

Since the display device is improved on the basis of the above display panel, the display device naturally inherits all the advantages of the display panel.

In sum, in a display panel and a method for manufacturing the same provided by the present disclosure, a conductive channel is formed by injecting conductive particles in the semiconductor layer with a large resistivity to reduce the resistivity of the doped region, thereby achieving connection between the first electrode and the heterotopic conductive wire, reducing the length of the wiring trace between the cathode and the heterotopic conductive wire, avoiding the touch blind region on the display panel caused by the excessively large wiring trace region, and improving the touch quality of the touch panel.

Although some exemplary embodiments of the present invention have been shown in the foregoing description, it will be understood by those skilled in the art that variations may be made to these exemplary embodiments without departing from the principles or spirit of the disclosure. The scope of the disclosure is defined by the claims and their equivalents.

1. A method for manufacturing a display panel comprising a substrate and a light emitting functional layer on the substrate, the method comprising the following steps:
forming a conductive wire on the substrate;
forming a semiconductor layer on the conductive wire;
forming a conductive channel in the semiconductor layer, the conductive channel connects to the conductive wire; and
forming a first electrode layer on the semiconductor layer and the light emitting functional layer, wherein the first electrode layer connects with the conductive channel.

2. The method for manufacturing a display panel according to claim 1, wherein forming a conductive channel in the semiconductor layer comprises injecting a material containing a conductive particle into the semiconductor layer by ion implantation to form the conductive channel.

3. The method for manufacturing a display panel according to claim 1, wherein the semiconductor layer comprises an organic semiconductor material and the conductive channel extends from a side of the semiconductor layer away from the substrate to the conductive wire.

4. The method for manufacturing a display panel according to claim 1, wherein forming a conductive channel in the semiconductor layer comprises:
covering a mask having a transmissive region over the semiconductor layer, and
performing ion implantation on a region of the semiconductor layer corresponding to the transmissive region to form the conductive channel in the region of the semiconductor layer corresponding to the transmissive region.

5. The method for manufacturing a display panel according to claim 1, wherein patterns of the conductive wire layer and the semiconductor layer are simultaneously formed by the same mask.

6. The method for manufacturing a display panel according to claim 2, wherein the conductive particle is at least one selected from a group consisting of a B³⁺ ion, a P³⁻ ion, an I⁻ ion, an organic conductive ion, an organic conductive atom and an organic conductive molecule.

7. The method for manufacturing a display panel according to claim 1, further comprising the step of forming an insulating layer on the substrate to isolate the conductive wire layer and the semiconductor layer from the light emitting functional layer.

8. The method for manufacturing a display panel according to claim 1, wherein the first electrode layer is multiplexed into a cathode of the light emitting function layer and a touch electrode, and segmentation of the first electrode layer is performed using a barrier technique to divide the first electrode layer into a plurality of mutually insulated sub-electrodes.

9. The method for manufacturing a display panel according to claim 8, wherein a projection of the barrier on the substrate does not overlap with a projection of the conductive channel on the substrate.

10. The method for manufacturing a display panel according to claim 8, wherein the barrier is an inverted trapezoidal spacer column.

11. A display panel comprising:
a substrate,
a conductive wire and a light emitting functional layer on the substrate,
a semiconductor layer on the conductive wire,
a first electrode layer on the light emitting functional layer and the semiconductor layer,
wherein the semiconductor layer is further provided with a conductive channel, and the first electrode layer is conductive to the conductive wire through the conductive channel.

12. The display panel according to claim 11, wherein the conductive channel comprises a conductive particle and the conductive particle is selected from the group consisting of a B³⁺ ion, a P³⁻⁰ ion, an I⁻ ion, an organic conductive ion, an organic conductive atom and an organic conductive molecule.

13. The display panel according to claim 11, wherein the display panel is manufactured by a method comprising the steps of:
forming a conductive wire on the substrate;
forming a semiconductor layer on the conductive wire;
forming a conductive channel in the semiconductor layer, the conductive channel connects to the conductive wire; and
forming a first electrode layer on the semiconductor layer and the light emitting functional layer, the first electrode layer connects to the conductive channel.

14. The display panel according to claim 11, wherein the conductive channel is formed by injecting a material containing a conductive particle into the semiconductor layer by ion implantation, and the conductive channel extends from a side of the semiconductor layer away from the substrate to the conductive wire.

15. The display panel according to claim 11, wherein a longitudinal axis of the conductive channel is perpendicular to both a surface of the semiconductor layer away from the substrate and a surface of the substrate.

16. A display device including a display panel comprising:
a substrate,
a conductive wire and a light emitting functional layer on the substrate,
a semiconductor layer on the conductive wire,
a first electrode layer on the light emitting functional layer and the semiconductor layer,
wherein the semiconductor layer is further provided with a conductive channel, and the first electrode layer is conductive to the conductive wire through the conductive channel.

17. The display device according to claim 16, wherein the conductive channel comprises a conductive particle and the conductive particle is selected from the group consisting of a B³⁺ ion, a P³⁻ ion, an I⁻ ion, an organic conductive ion, an organic conductive atom and an organic conductive molecule.

18. The display device according to claim 16, wherein the display panel is manufactured by a method comprising the steps of:
forming a conductive wire on the substrate;
forming a semiconductor layer on the conductive wire;
forming a conductive channel in the semiconductor layer, the conductive channel connects to the conductive wire; and
forming a first electrode layer on the semiconductor layer and the light emitting functional layer, wherein the first electrode layer connects with the conductive channel.

19. The display device according to claim 16, wherein the conductive channel is formed by injecting a material containing a conductive particle into the semiconductor layer by ion implantation, and the conductive channel extends from a side of the semiconductor layer away from the substrate to the conductive wire.

20. The display device according to claim 16, wherein a longitudinal axis of the conductive channel is perpendicular to a surface of the semiconductor layer away from the substrate and a surface of the substrate.
